(19) United States
(12) Patent Application Publication
(10) Pub. No.: US 2011/0127562 A1
(43) Pub. Date: Jun. 2, 2011

(54) Electronic Substrate Having Low Current Leakage and High Thermal Conductivity and Associated Methods

(76) Inventors: Chien-Min Sung, (US); Ming Chi Kan, Rende Township (TW); Shao Chung Hu, Xindian City (TW)

(21) Appl. No.: 12/787,074

(22) Filed: May 25, 2010

Related U.S. Application Data
(60) Provisional application No. 61/228,020, filed on Jul. 23, 2009.

(51) Int. Cl. H01L 33/00; H05K 1/02; H05K 3/00

(52) U.S. Cl. 257/99; 174/250; 29/829; 257/E33.066

(57) ABSTRACT

Electrical substrates having low current leakage and high thermal conductivity, including associated methods, are provided. In one aspect for example, a multilayer substrate having improved thermal conductivity and dielectric properties can include a metal layer having a working surface with a local Ra of greater than about 0.1 micron, a dielectric layer coated on the working surface of the metal layer, and a thermally conductive insulating layer disposed on the dielectric layer, wherein the multilayer substrate has a minimum resistivity between the metal layer and the thermally conductive insulating layer across all of the working surface of at least 1×10⁶ ohms.

### PRIORITY DATA

This application claims the benefit of U.S. Provisional Patent Application Ser. No. 61/228,020, filed on Jul. 23, 2009 which is incorporated herein by reference.

### FIELD OF THE INVENTION

The present invention relates generally to electronic substrates and associated methods. Accordingly, the present invention involves the electrical and material science fields.

### BACKGROUND OF THE INVENTION

In many developed countries, major portions of the populations consider electronic devices to be integral to their lives. Such increasing use and dependence has generated a demand for electronics devices that are smaller and faster. As electronic circuitry increases in speed and decreases in size, cooling of such devices becomes problematic.

Electronic devices generally contain printed circuit boards having integrally connected electronic components that allow the overall functionality of the device. These electronic components, such as processors, transistors, resistors, capacitors, light-emitting diodes (LEDs), etc., generate significant amounts of heat. As it builds, heat can cause various thermal problems associated with such electronic components. Significant amounts of heat can affect the reliability of an electronic device, or even cause it to fail by, for example, causing burn out or shorting both within the electronic components themselves and across the surface of the printed circuit board. Thus, the buildup of heat can ultimately affect the functional life of the electronic device. This is particularly problematic for electronic components with high power and high current demands, as well as for the printed circuit boards that support them.

Various cooling devices have been employed such as fans, heat sinks, Peltier and liquid cooling devices, etc., as means of reducing heat buildup in electronic devices. As increased speed and power consumption cause increasing heat buildup, such cooling devices generally must increase in size to be effective and may also require power to operate. For example, fans must be increased in size and speed to increase airflow, and heat sinks must be increased in size to increase heat capacity and surface area. The demand for smaller electronic devices, however, not only precludes increasing the size of such cooling devices, but may also require a significant size decrease.

Other approaches have utilized heat conductive materials as substrates for electronic devices. While heat conductive materials can improve thermal management of some devices, such materials are often electrically conductive as well. Electrically insulative layers have been used in an attempt to prevent current leakage between the electrical components and the electrically conductive board. This approach has been problematic due to the generally low thermal conductivity of electrically insulative materials. As such, insulative materials that are sufficiently thin to allow heat conductivity provide poor electrical insulation, causing current leakage between the substrate and the electrical components, particularly in areas where the substrate has rough spots or foreign debris thereon.

As a result, methods and associated devices are being sought to provide adequate cooling of electronic devices while minimizing current leakage.

### SUMMARY OF THE INVENTION

Accordingly, the present invention provides electronic substrates having low current leakage and high thermal conductivity, including associated methods. In one aspect for example, a multilayer substrate having improved thermal conductivity and dielectric properties can include a metal layer or board having a working surface with a local Ra (average roughness) of greater than about 0.1 micron, a dielectric layer coated on the working surface of the metal layer, and a thermally conductive insulating layer disposed on the dielectric layer, wherein the multilayer substrate has a minimum resistivity between the metal layer and the thermally conductive insulating layer across all of the working surface of at least 10⁷ ohms. Additionally, although a variety of metal substrates can be utilized, in one aspect the metal layer includes a material selected from the group consisting of Al, Cu, and combinations thereof.

The thicknesses of the dielectric layer and the thermally conductive insulating layer can be of any useful thickness that could allow low current leakage and has high thermal conductivity. In one aspect, however, the dielectric layer has a thickness that is less than the local Ra of the working surface. In another aspect, the thermally conductive insulating layer has a thickness that is less than the local Ra of the working surface. In yet another aspect, thermally conductive insulating layer and the dielectric layer have a combined thickness that is greater than the local Ra of the working surface.

Furthermore, a variety of materials can be utilized for the construction of the dielectric layer. In one aspect, for example, the dielectric layer can include an oxide, a nitride, a carbide, or a combinations thereof. As a more specific example, the dielectric layer can include Al₂O₃, AlN, TiC, or a combination thereof. In another specific example, the metal layer is Al and the dielectric layer is an oxidized Al₂O₃ portion of the metal layer.

Similarly, various materials can be utilized in the construction of the thermally conductive insulating layer. It is noted that any material having a thermal conductivity that is greater than the thermal conductivity of the dielectric layer while at the same time providing electrical insulation between the dielectric layer and any overlying electrical components should be considered to be within the present scope. In one aspect, however, the thermally conductive insulating layer can include DLC, AlN, BN, or a combination thereof. In one specific aspect, the thermally conductive insulating layer is DLC. In another specific aspect, the DLC layer is substantially bonded in an sp³ configuration. In yet another specific aspect, the DLC layer is substantially hydrogen terminated. In a further specific aspect, the DLC layer is substantially bonded in an sp³ configuration and substantially hydrogen terminated.

The present invention additionally provides a method of minimizing current leakage between a metal layer and an electrical component that provides improved thermal conductivity. Such a method can include applying a dielectric layer to a metal layer, wherein the metal layer has a local Ra of at least 0.1 micron and the dielectric layer has a thickness that is less than the local Ra of the metal layer, and applying a DLC layer to the dielectric layer, wherein the DLC layer has a thickness that is less than the local Ra of the metal layer, wherein the dielectric layer and the DLC layer have a combined thickness that is greater than the local Ra of the metal layer, and wherein the combined thickness is sufficient to minimize current leakage.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-section view of a prior art electronic substrate.

FIG. 2 is a cross-section view of an electronic substrate in accordance with one embodiment of the present invention.

FIG. 3 is a cross-section view of a prior art electronic substrate.

FIG. 4 is a cross-section view of an electronic substrate in accordance with one embodiment of the present invention.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a dopant” includes reference to one or more of such dopants, and reference to “the diamond layer” includes reference to one or more of such layers.

As used herein, “vapor deposited” refers to materials which are formed using vapor deposition techniques. “Vapor deposition” refers to a process of forming or depositing materials on a substrate through the vapor phase. Vapor deposition processes can include any process such as, but not limited to, chemical vapor deposition (CVD) and physical vapor deposition (PVD). A wide variety of variations of each vapor deposition method can be performed by those skilled in the art. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, and the like.

As used herein, “chemical vapor deposition,” or “CVD” refers to any method of chemically forming or depositing diamond particles in a vapor form upon a surface. Various CVD techniques are well known in the art.

As used herein, “physical vapor deposition,” or “PVD” refers to any method of physically forming or depositing diamond particles in a vapor form upon a surface. Various PVD techniques are well known in the art.

As used herein, “diamond” refers to a crystalline structure of carbon atoms bonded to other carbon atoms in a lattice of tetrahedral coordination known as sp³ bonding. Specifically, each carbon atom is surrounded by and bonded to four other carbon atoms, each located on the tip of a regular tetrahedron. Further, the bond length between any two carbon atoms is 1.54 angstroms at ambient temperature conditions, and the angle between any two bonds is 109 degrees, 28 minutes, and 16 seconds although experimental results may vary slightly. The structure and nature of diamond, including its physical and electrical properties are well known in the art.

As used herein, “distorted tetrahedral coordination” refers to a tetrahedral bonding configuration of carbon atoms that is irregular, or has deviated from the normal tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond.

As used herein, “diamond-like carbon” refers to a carbonaceous material having carbon atoms as the majority element, with a substantial amount of such carbon atoms bonded in distorted tetrahedral coordination. Diamond-like carbon (DLC) can typically be formed by PVD processes, although CVD or other processes could be used such as vapor deposition processes. Notably, a variety of other elements can be included in the DLC material as either impurities, or as dopants, including without limitation, hydrogen, sulfur, phosphorous, boron, nitrogen, silicon, tungsten, etc.

As used herein, “amorphous diamond” refers to a type of diamond-like carbon having carbon atoms as the majority element, with a substantial amount of such carbon atoms bonded in distorted tetrahedral coordination. In one aspect, the amount of carbon in the amorphous diamond can be at least about 90%, with at least about 20% of such carbon being bonded in distorted tetrahedral coordination. Amorphous diamond also has a higher atomic density than that of diamond (176 atoms/cm³). Further, amorphous diamond and diamond materials contract upon melting.

The terms “thermal transfer,” “thermal movement,” and “thermal transmission” can be used interchangeably, and refer to the movement of heat from an area of higher temperature to an area of cooler temperature. It is intended that the movement of heat include any mechanism of thermal transmission known to one skilled in the art, such as, without limitation, conductive, convective, radiative, etc.

As used herein, the term “emitting” refers to the process of moving heat or light from a solid material into the air.

As is used herein, the terms “flat” and “flatness” are used to refer to the flatness of a substrate in both the global and local sense. Global flatness is defined as the amount of bowing that occurs across the substrate. Local flatness refers to the roughness of the substrate, usually referred to as Ra. Thus, “Ra” refers to a measure of the roughness of a surface as determined by the difference in height between a peak and a neighboring valley.

As used herein, “substrate” refers to a support surface to which various materials can be joined in forming an electronic component or device. The substrate may be any shape, thickness, or material, required in order to achieve a specific result, and includes but is not limited to metals, alloys, ceramics, and mixtures thereof. Further, in some aspects, the substrate may be an existing semiconductor device or wafer, or may be a material which is capable of being joined to a suitable device.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

### THE INVENTION

The present invention provides substrate structures for supporting an electronic component thereon having improved dielectric and thermally conductive properties. Many materials that exhibit good thermally conductive properties often tend to also have good electrically conductive properties. While support substrates made from electrically conductive materials such as metals can assist in transferring heat away from electronic components disposed thereon, these materials can also cause short circuits or current leakage, thus decreasing the effectiveness of the electronic component. In order to minimize such current leakage, an insulative layer can be disposed between the metal board and the electronic component. This approach, however, is less than ideal due to the nature of many insulative materials, which tend to have poor thermal conductivity. Thus, a thick insulative layer does not effectively transfer heat to the underlying metal substrate. Utilizing a thin insulative layer can improve the thermal transfer of heat to the metal support; however thin insulative layers tend to have pinholes and/or microcracks where current leakage can occur, thus limiting the effectiveness of the insulative layer. This problem of pinholes and microcracks is further exacerbated by the typical surface roughness of most commercially available metal support layers, such as aluminum. A second insulating layer, such as epoxy, can be used to reduce current leakage; however thermal conductivity will be reduced as well. Additionally, epoxy coatings are subject to environmental degradation, particularly when used in outdoor environments.

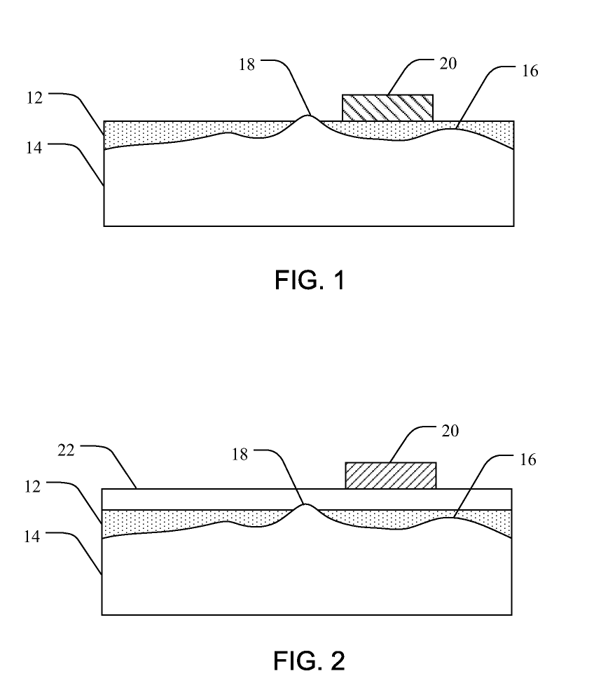

The inventors have discovered that a composite structure can be formed having a high thermal conductivity that has greatly reduced if not eliminated current leakage. As is shown in FIG. 1, a dielectric layer 12 can be disposed on a metal layer 14 to provide electrical insulation to the metal layer. The underlying surface roughness of the metal layer 14 has high points that either limit the thickness of 16, or protrude from 18, the dielectric layer. This surface roughness can be a result of the local Ra of the metal layer or it can be due to debris on the metal surface. An electrical component 20 (e.g. an electrical trace) that is disposed on the dielectric layer 12 can short circuit at locations such as these, thus causing current leakage and reduced performance of the device. Increasing the thickness of the dielectric layer to account for the thin spots of the dielectric layer can reduce current leakage; however this increased thickness most often greatly reduces the thermal cooling of the device. As is shown in FIG. 2, a thermally conductive insulating layer 22 can be disposed on the dielectric layer 12 to improve the insulative properties of the dielectric layer while at the same time allowing improved thermal transmission of heat. This thermally conductive insulating layer functions to, inter alia, fill in the thin spots of the dielectric layer to reduce or prevent current leakage, while at the same time improving the thermal emission of the device. Note that the portion of the metal layer that protrudes from 18 the dielectric layer contacts the thermally conductive insulating layer.

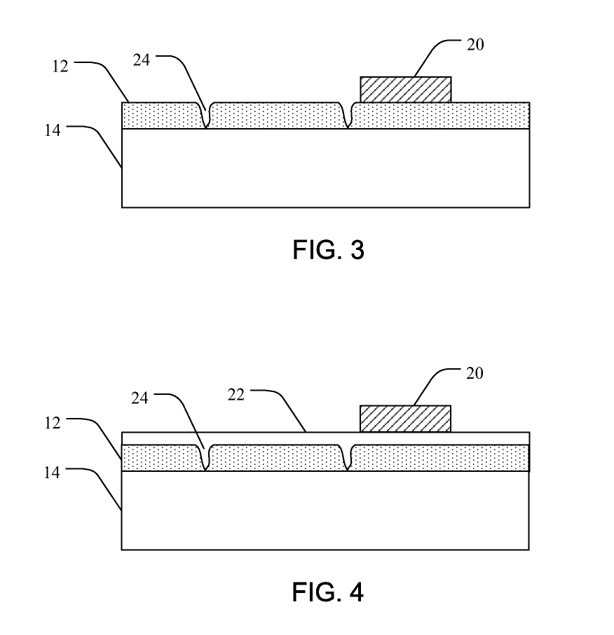

Another situation that can cause current leakage includes microcracks and/or pinholes in the dielectric layer, as is shown in FIG. 3. These microcracks and pinholes 24 can extend through the dielectric layer 12 all the way to the metal layer 14, or in some cases, merely extend close enough to allow current leakage between the metal layer 14 and an electrical component 20. As is shown in FIG. 4, the conductive insulating layer 22 can be applied to the dielectric layer 12 to fill the microcracks and/or pinholes 24 and thus eliminate the potential current leakage.

Accordingly, in one aspect a multilayer substrate having improved thermal conductivity and dielectric properties is provided. Such a substrate can include a metal layer having a working surface with a local Ra of greater than about 0.1 micron, a dielectric layer coated on the working surface of the metal layer, and a thermally conductive insulating layer disposed on the dielectric layer. The multilayer substrate has a minimum resistivity between the metal layer and the thermally conductive insulating layer across all of the working surface of at least 10⁷ ohms. In other words, the resistivity between the metal layer and the thermally conductive insulating layer at any given point across the surface of the substrate is greater than or equal to 5×10⁶ ohms. In another aspect, the minimum resistivity between the metal layer and the thermally conductive insulating layer across all of the working surface is at least 1×10⁶ ohms. Thus a composite insulative/thermally conductive layer can greatly reduce voltage breakdown and subsequent current leakage between the metal layer and the overlying electrical components, while at the same time facilitating improved heat transmission and therefore enhanced thermal cooling to the device.

A variety of metal materials are contemplated for use in the metal layer of the present invention. The selection of the metal materials can be dependent on the intended use and configuration of the device, the type of thermally conductive insulating layer to be used, as well as compatibility with the dielectric layer. One reason for using a metal layer as a substrate material is the improved thermal conductivity of many metal materials. As such, metals having a high thermal conductivity can be utilized. Non-limiting examples of useful metal layer materials include Al, Cu, and alloys and mixtures thereof. As such, while Cu and Al metals may be used, the present scope includes, in addition to alloys, composites such as rolled Al film on Cu, platted Cu on Al, and the like.

The dielectric layers of the present invention can include numerous materials, depending on a variety of factors, including the type of metal being used, the nature of the thermally conductive insulating layer, and the nature and intended use of the electronic device. In one aspect, for example, the dielectric layer can be an oxide, a nitride, a carbide, or a combinations thereof. Specific non-limiting examples of oxides include Al₂O₃, AlN, SiC, and the like. In one specific example, the dielectric layer can be an oxide such as Al₂O₃. If the metal layer is aluminum, one convenient method for depositing or forming an oxide layer would include oxidizing the aluminum metal to form the Al₂O₃ of a sufficient thickness. Specific non-limiting examples of nitrides include AlN, BN, Si₃N4, and the like. In one specific example, the dielectric layer can be a nitride such as AlN. Specific non-limiting examples of carbides include TiC, SiC, SiC:H, TiC, and the like. In one specific example, the dielectric layer can be a carbide such as TiC.

The dielectric layer is intended to cover enough of the metal layer surface such that current leakage is minimized or eliminated. In some aspects this would include an entire surface of the metal layer, while in other aspects only a portion of a surface would be coated. Additionally, for some applications it can be beneficial to coat the dielectric layer on multiple sides of the metal layer. Such a configuration can be particularly useful for those metal layers having heat-generating electrical components located on multiple sides. Such a configuration allows dielectric insulation and thermal cooling from all sides of the metal layer where heat can originate. In addition, it can be beneficial using certain processes to add the dielectric layer to multiple or all sides of the metal layer, regardless of whether or not electrical components are located on multiple sides. For example, if an aluminum metal layer is to be oxidized or anodized using a submerging process, it can be more effective to simply oxidize multiple sides of the metal layer due to the ease of submerging the entire metal layer in the oxidizing composition.

The thickness of the dielectric layer should be sufficient to provide an insulative benefit to the metal layer and yet thin enough to allow effective thermal transmission therethrough to the thermally conductive insulating layer. For example, in one aspect, the thickness of the dielectric layer can be less than about 1 micron thick. In another aspect, the thickness of the dielectric layer can be less than about 500 nanometers thick. In yet another aspect, the thickness of the dielectric layer can be less than about 250 nanometers thick. In a further aspect, the thickness of the dielectric layer can be less than about 100 nanometers thick. In yet a further aspect, the thickness of the dielectric layer can be less than about 50 nanometers thick. In another aspect, the thickness of the dielectric layer can be from about 1 micron to about 50 microns thick. In yet another aspect, the dielectric layer can be from about 10 microns to about 30 microns thick. Furthermore, the thickness of the dielectric layer can be expressed in terms of the local Ra of the metal layer. In one aspect, for example, the dielectric layer has a thickness that is less than the local Ra of the working surface. In another aspect the thickness can be about 5% less than the local Ra (i.e. 95% as thick as the Ra is high). In yet another aspect, the thickness can be about 10% less than the local Ra. In another aspect, the thickness can be over 20% less than the local Ra. In a further aspect, the thickness of the layer can be over 50% less than the local Ra. In an additional aspect, the thickness of the dielectric layer can be from about 50% to about 80% less than the local Ra (i.e. about 20% to 50% as tall as the Ra height).

The thermally conductive insulating layer materials should be materials that are electrically insulative and thermally conductive. Thus, this layer functions to enhance the insulative properties of the dielectric layer, particularly in those areas where the dielectric layer is thin, without providing a significant thermal barrier to the transfer of heat from the device. Various materials can be used, provided the above conditions are met and the material has the capability of being coated on the dielectric layer. In one aspect, for example, the thermally conductive insulating layer can include materials such as DLC, AlN, BN, and the like, including combinations thereof.

In one specific aspect, the thermally conductive insulating layer is DLC. DLC materials can be electrically insulative and thermally conductive, depending on the configuration of the DLC material itself. For example, the more sp³ content a DLC material has, the greater the dielectric property and the thermal conduction of the DLC layer. Accordingly, electrically insulating DLC materials should have minimal sp² content to maximize electrical insulation and thermal conductivity. Additionally, hydrogen terminated DLC materials have greater dielectric properties, but reduced thermal conductivity. A DLC material with optimal dielectric and thermal properties can therefore be produced through a balance of sp³ bonding and hydrogen termination. Thus, various DLC materials can be utilized as a thermally conductive insulating layer according to aspects of the present invention. For example, in one aspect, the DLC layer is substantially bonded in an sp³ configuration. In another aspect, the DLC layer is substantially hydrogen terminated. In yet another aspect, the DLC layer is substantially bonded in an sp³ configuration and substantially hydrogen terminated.

The interaction between the materials of the dielectric layer and the thermally conductive insulating layer can be a factor in the selection of appropriate materials. Thus, adhesion can be facilitated between the layers by selecting materials that are compatible with one another. In some cases, however, an interlayer can be utilized between the dielectric layer and the thermally conductive insulating layer to facilitate or to strengthen this interaction. Numerous interlayer materials are contemplated, and are thus variable depending on the nature of the materials used in the dielectric and thermally conductive insulating layers. In one aspect, for example, the interlayer can be a carbide former. Such a carbide former can be particularly useful for facilitating the deposition of DLC onto a variety of dielectric materials.

The thickness of the thermally conductive insulating layer should be thick enough to insulate the thin regions of the dielectric layer that can be prone to current leakage. For example, in one aspect, the thickness of the thermally conductive insulating layer can be less than about 1 micron thick. In another aspect, the thickness of the thermally conductive insulating layer can be less than about 500 nanometers thick. In yet another aspect, the thickness of the thermally conductive insulating layer can be less than about 250 nanometers thick. In a further aspect, the thickness of the thermally conductive insulating layer can be less than about 100 nanometers thick. In yet a further aspect, the thickness of the thermally conductive insulating layer can be less than about 50 nanometers thick. In another aspect, the thickness of the thermally conductive insulating layer can be from about 1 micron to about 5 microns thick. Furthermore, the thickness of the thermally conductive insulating layer can be expressed in terms of the local Ra of the metal layer. In one aspect, for example, the thermally conductive insulating layer has a thickness that is less than the local Ra of the working surface. In another aspect the thickness can be about 5% less than the local Ra (i.e. 95% as thick as the Ra is high). In yet another aspect, the thickness can be about 10% less than the local Ra. In another aspect, the thickness can be over 20% less than the local Ra. In a further aspect, the thickness of the layer can be over 50% less than the local Ra. In an additional aspect, the thickness of the thermally conductive insulating layer can be from about 50% to about 80% less than the local Ra (i.e. about 20% to 50% as tall as the Ra height).

Furthermore, the combined thickness of both the dielectric layer and the thermally conductive insulating layer can be expressed in terms of the local Ra of the metal layer. For example, in one aspect, the thermally conductive insulating layer and the dielectric layer have a combined thickness that is greater than the local Ra of the working surface. In another aspect, the combined thickness can be at least about 10% greater than the local Ra (i.e. 110% of the height of the Ra). In yet another aspect, the combined thickness can be from about 10% greater to about 500% greater than the local RA. In a further aspect, the combined thickness can be more than about 20%, 30%, 40%, 50%, or 100% greater than the local Ra. In an additional aspect, the combined thickness can be from about 80% to about 400% greater than the local Ra.

Returning to DLC layers, diamond materials have excellent thermal conductivity properties that make them ideal for incorporation into electronics devices. The transfer of heat that is present in an electronic device can thus be accelerated from the device through a diamond material such as DLC. It should be noted that the present invention is not limited as to specific theories of heat transmission. As such, in one aspect the accelerated movement of heat from inside the device can be at least partially due to heat movement into and through a DLC layer. Due to the heat conductive properties of diamond, heat can rapidly spread laterally through the DLC layer. Heat present around the edges of the device, and thus further away from the heat source, will be more rapidly dissipated into the air or into surrounding structures, such as heat spreaders or device supports. Additionally, DLC layers having a portion of surface area exposed to air will more rapidly dissipate heat from a device in which such a layer is incorporated. Because the thermal conductivity of diamond is greater than the thermal conductivity of other materials in the electronic device or other structure to which it is thermally coupled, a heat sink or spreader is established by the DLC layer. Thus heat that builds up in the device is drawn into the DLC layer and spread laterally to be discharged from the device. Such accelerated heat transfer can result in electronic devices with much cooler operational temperatures. Additionally, the acceleration of heat transfer not only cools an electronic device, but may also reduce the heat load on many associated electronic components.

It should be understood that the following is a very general discussion of diamond deposition techniques that may or may not apply to a particular layer or application, and that such techniques may vary widely between the various aspects of the present invention. Generally, diamond layers may be formed by any means known, including various vapor deposition techniques. Any number of known vapor deposition techniques may be used to form these diamond layers. The most common vapor deposition techniques include chemical vapor deposition (CVD) and physical vapor deposition (PVD), although any similar method can be used if similar properties and results are obtained. In one aspect, CVD techniques such as hot filament, microwave plasma, oxyacetylene flame, rf-CVD, laser CVD (LCVD), metal-organic CVD (MOCVD), laser ablation, conformal diamond coating processes, and direct current arc techniques may be utilized. Typical CVD techniques use gas reactants to deposit the diamond or diamond-like material in a layer, or film. These gases generally include a small amount (i.e. less than about 5%) of a carbonaceous material, such as methane, diluted in hydrogen. A variety of specific CVD processes, including equipment and conditions, as well as those used for boron nitride layers, are well known to those skilled in the art. In another aspect, PVD techniques such as sputtering, cathodic arc, and thermal evaporation may be utilized. Further, specific deposition conditions may be used in order to adjust the exact type of material to be deposited, whether DLC, amorphous diamond, or pure diamond.

As has been described, an optional nucleation enhancing layer can be formed on the dielectric layer in order to improve the quality and deposition time of a DLC layer. Specifically, a DLC layer can be formed by depositing applicable nuclei, such as diamond nuclei, on the dielectric layer and then growing the nuclei into a film or layer using a vapor deposition technique. In one aspect of the present invention, a thin nucleation enhancer layer can be coated upon the dielectric layer to enhance the growth of the DLC layer. Diamond nuclei are then placed upon the nucleation enhancer layer, and the growth of the diamond layer proceeds via CVD or PVD as possible deposition techniques.

A variety of suitable materials will be recognized by those in skilled in the art which can serve as a nucleation enhancer. In one aspect of the present invention, the nucleation enhancer may be a material selected from the group consisting of metals, metal alloys, metal compounds, carbides, carbide formers, and mixtures thereof. Examples of carbide forming materials may include, without limitation, tungsten (W), tantalum (Ta), titanium (Ti), zirconium (Zr), chromium (Cr), molybdenum (Mo), silicon (Si), and manganese (Mn). Additionally, examples of carbides include tungsten carbide (WC), silicon carbide (SiC), titanium carbide (TiC), zirconium carbide (ZrC), and mixtures thereof among others.

The nucleation enhancer layer, when used, is a layer which is thin enough that it does not to adversely affect the thermal transmission properties of the DLC layer. In one aspect, the thickness of the nucleation enhancer layer may be less than about 0.1 micrometers. In another aspect, the thickness may be less than about 10 nanometers. In yet another aspect, the thickness of the nucleation enhancer layer is less than about 5 nanometers. In a further aspect of the invention, the thickness of the nucleation enhancer layer is less than about 3 nanometers.

Various methods can be employed to increase the quality of the diamond in the nucleation surface of the DLC layer that is created by various deposition techniques. For example, diamond particle quality can be increased by reducing the methane flow rate, and increasing the total gas pressure during the early phase of diamond deposition. Such measures decrease the decomposition rate of carbon, and increase the concentration of hydrogen atoms. Thus a significantly higher percentage of the carbon will be deposited in a sp³ bonding configuration, and the quality of the diamond nuclei (and thus the DLC layer) formed is increased. Additionally, the nucleation rate of diamond particles deposited on the dielectric layer or the nucleation enhancer layer may be increased in order to reduce the amount of interstitial space between diamond particles. Examples of ways to increase nucleation rates include, but are not limited to; applying a negative bias in an appropriate amount, often about 100 volts, to the growth surface; polishing the growth surface with a fine diamond paste or powder, which may partially remain on the growth surface; and controlling the composition of the growth surface such as by ion implantation of C, Si, Cr, Mn, Ti, V, Zr, W, Mo, Ta, and the like by PVD or PECVD. PVD processes are typically at lower temperatures than CVD processes and in some cases can be below about 200° C. such as about 150° C. Other methods of increasing diamond nucleation will be readily apparent to those skilled in the art.

In one aspect of the present invention, the DLC layer may be formed as a conformal diamond layer. Conformal diamond coating processes can provide a number of advantages over conventional diamond film processes. Conformal diamond coating can be performed on a wide variety of substrates, including non-planar substrates. A growth surface can be pretreated under diamond growth conditions in the absence of a bias to form a carbon film. The diamond growth conditions can be conditions that are conventional CVD deposition conditions for diamond without an applied bias. As a result, a thin carbon film can be formed which is typically less than about 100 angstroms. The pretreatment step can be performed at almost any growth temperature such as from about 200° C. to about 900° C., although lower temperatures below about 500° C. may be preferred. Without being bound to any particular theory, the thin carbon film appears to form within a short time, e.g., less than one hour, and is a hydrogen terminated amorphous carbon.

Following formation of the thin carbon film, the growth surface can then be subjected to diamond growth conditions to form a conformal diamond layer. The diamond growth conditions may be those conditions that are commonly used in traditional CVD diamond growth. However, unlike conventional diamond film growth, the diamond film produced using the above pretreatment steps results in a conformal diamond film that typically begins growth substantially over the entire growth surface with substantially no incubation time. In addition, a continuous film, e.g. substantially no grain boundaries, can develop within about 80 nm of growth. Diamond layers having substantially no grain boundaries may move heat more efficiently than those layers having grain boundaries.

The resulting electronic substrates can be utilized for any application for which such a substrate would be useful. General examples of such devices can include LEDs, laser diodes, p-n junction devices, p-i-n junction devices, SAW and BAW filters, electronic circuitry, transistors, CPUs, and the like. Additionally, devices that are prone to environmental damage can benefit from the substrates described herein. As an example, LED streetlights can be beneficial due to their low power consumption and prolonged use. In many cases, however, electronic substrates begin to break down in an outdoor environment. The electronic substrates of the present invention are more durable in such environments, particularly for those embodiments where the thermally conductive insulating layer is a DLC material.

### EXAMPLES

The following examples illustrate various techniques of making electronic substrates according to aspects of the present invention. However, it is to be understood that the following are only exemplary or illustrative of the application of the principles of the present invention. Numerous modifications and alternative compositions, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

An Al metal board is anodized in an electrolyte to cause the surface to oxidize to a thickness of about 20 microns. The aluminum oxide so formed is deposited with silicon-carbon-hydrogen interlayer, and then overcoated by a 2 micron thick layer of hydrogen terminated DLC by RFCVD. A chromium coating is applied over the DLC layer as a carbide former, and copper is deposited by plating onto the chromium layer. The copper layer is then partially etched to form electrical circuits for the attachment of an LED.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A multilayer substrate having improved thermal conductivity and dielectric properties, comprising:
a metal layer having a working surface with a local Ra of greater than about 0.1 micron;
a dielectric layer coated on the working surface of the metal layer; and
a thermally conductive insulating layer disposed on the dielectric layer, wherein the multilayer substrate has a minimum resistivity between the metal layer and the thermally conductive insulating layer across all of the working surface of at least 1×10⁶ ohms.

2. The substrate of claim 1, wherein the metal layer includes a material selected from the group consisting of Al, Cu, and combinations thereof.

3. The substrate of claim 1, wherein the dielectric layer has a thickness that is less than the local Ra of the working surface.

4. The substrate of claim 3, wherein the thermally conductive insulating layer has a thickness that is less than the local Ra of the working surface.

5. The substrate of claim 4, wherein the thermally conductive insulating layer and the dielectric layer have a combined thickness that is greater than the local Ra of the working surface.

6. The substrate of claim 1, wherein the dielectric layer includes a member selected from the group consisting of oxides, nitrides, carbides, and combinations thereof.

7. The substrate of claim 1, wherein the dielectric layer includes a member selected from the group consisting of Al₂O₃, AlN, TiC, and combinations thereof.

8. The substrate of claim 2, wherein the metal layer is Al and the dielectric layer is an oxidized Al₂O₃ portion of the metal layer.

9. The substrate of claim 1, wherein the thermally conductive insulating layer includes a member selected from the group consisting of DLC, AlN, BN, and combinations thereof.

10. The substrate of claim 1, wherein the thermally conductive insulating layer is DLC.

11. The substrate of claim 10, wherein the DLC layer is substantially bonded in an sp³ configuration.

12. The substrate of claim 10, wherein at least 50% of the DLC layer is bonded in an sp³ configuration.

13. The substrate of claim 10, wherein the DLC layer is substantially hydrogen terminated.

14. The substrate of claim 10, wherein the DLC layer is substantially bonded in an sp³ configuration and substantially hydrogen terminated.

15. The substrate of claim 1, wherein the working surface of the metal layer has a local Ra of greater than about 0.3 microns.

16. The substrate of claim 1, wherein the minimum resistivity between the metal layer and the thermally conductive insulating layer across all of the working surface is at least 1×10⁶ ohms.

17. The substrate of claim 1, wherein the metal layer is sufficiently rough such that a portion protrudes through the dielectric layer and contacts the thermally conductive insulating layer.

18. The substrate of claim 1, wherein a carbide former is disposed between the dielectric layer and the thermally conductive insulating layer.

19. A method of minimizing current leakage between a metal layer and an electrical component that provides improved thermal conductivity, comprising:
applying a dielectric layer to a metal layer, wherein the metal layer has a local Ra of at least 0.1 micron and the dielectric layer has a thickness that is less than the local Ra of the metal layer; and
applying a DLC layer to the dielectric layer, wherein the DLC layer has a thickness that is less than the local Ra of the metal layer, wherein the dielectric layer and the DLC layer have a combined thickness that is greater than the local Ra of the metal layer, and wherein the combined thickness is sufficient to minimize current leakage.

20. An LED device, comprising:
the multilayer substrate as in claim 1, wherein the multilayer substrate includes electrical interconnects; and
an LED coupled to the multilayer substrate and electrically coupled to the electrical interconnects.
